(19) United States
(12) Patent Application Publication
(10) Pub. No.: US 2014/0347821 A1
(43) Pub. Date: Nov. 27, 2014

(54) THERMALLY CONDUCTIVE AND ELECTRICALLY INSULATING LINK BETWEEN AT LEAST ONE ELECTRONIC COMPONENT AND A COMPLETELY OR PARTIALLY METAL RADIATOR

(71) Applicant: Valeo Systemes de Controle Moteur, Cergy Saint Christophe (FR)

(72) Inventors: Larbi Bendani, Meru (FR); Mimoun Askeur, Vaureal (FR); Francis Delaporte, Limay (FR)

(21) Appl. No.: 14/364,775

(22) PCT Filed: Dec. 10, 2012
(86) PCT No.: PCT/FR2012/052862

§ 371 Date: Jun. 12, 2014

(30) Foreign Application Priority Data
Dec. 15, 2011 (FR) 1161692

(51) Int. Cl. H05K 3/28; C25D 11/00; H05K 1/02

(52) U.S. Cl. CPC H05K 3/28; H05K 1/021; C25D 11/00; H05K 2201/066; H05K 2203/0723
USPC 361/720; 205/324

(57) ABSTRACT

The invention relates to a method for producing a thermally conductive and electrically insulating link between at least one electronic component (2) and a completely or partially metal radiator (5), in which the electronic component (2) and the radiator (5) form part of an assembly (1) also comprising a printed circuit (4) disposed between the electronic component (2) and the radiator (5), said printed circuit (4) comprising at least one metal layer (8, 9) and a metal insert (13). According to the method, at least one metal surface (11, 12, 15, 16, 17) is anodised and the heat from the electronic component (2) is dissipated through said surface to the radiator (5), said metal surface belonging to one of the following: the electronic component (2), the printed circuit (4) or the radiator (5).

The present invention relates to the production of a thermally conductive and electrically insulating connection between at least one electronic component and a radiator. In the context of the invention, the expression “electrically insulating connection” must be understood to mean a connection that ensures the continuity of electrical signals and their insulation. “Electrically insulating” is defined according to standard IPC TM650.

Still in the context of the invention, a connection is thermally conductive when it has a thermal resistance with a value comprised between 1.5° C./W and 3.5° C./W for powers of 10 W to 20 W.

Generally, to measure the thermal resistance of a printed circuit board, a MOS transistor may be soldered to this printed circuit board and a current may be injected into the internal diode of this transistor. Voltage measurements on either side of this printed circuit board give, based on the specifications of the printed circuit board published by the manufacturer, the variation in temperature.

Once the thermal resistance of the printed circuit board is known, it is possible to proceed in the same way for an assembly comprising the printed circuit board and the carrier and measure the voltage on either side of this assembly. The thermal resistance of the assembly may be deduced therefrom, and hence, by subtraction of the thermal resistance of the printed circuit board, the thermal resistance of the carrier.

The invention is especially but not exclusively applicable to electronic components employed as power switches forming part of an inverter. This inverter for example belongs to an inverter/charger circuit furthermore comprising an electric motor, and incorporated into an electric or hybrid vehicle.

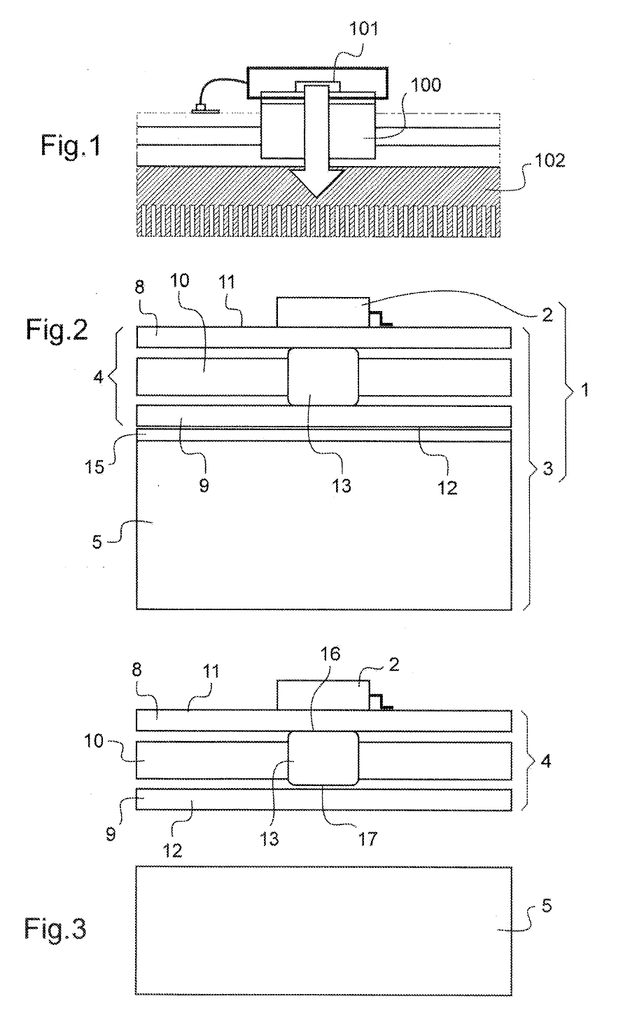

The electronic component and the radiator form part of an assembly comprising a printed circuit board through which heat dissipated by the electronic component is transferred to the radiator. It is known, as shown for example in FIG. 1, to insert a metal insert 100, made of copper for example, into the printed circuit board in order to promote the transfer of the heat generated by the electronic component 101 to the radiator 102. When the electronic component 101 is supplied with a high voltage and/or high currents, a greater amount of heat is generated and the electrical insulation required between the electronic component 101 and the radiator 102 is increased.

Patent application EP 2 023 706 describes anodizing a layer of an insert placed between a radiator and an electronic component. The insert extends beyond a printed circuit board to the radiator.

Patent U.S. Pat. No. 6,449,158 describes placing an electronic component in a cavity in a printed circuit board, and interposing an anodized aluminum layer between this electronic component and a radiator. Thus, the electronic component is not borne by an external face of the printed circuit board.

There is a need to ensure good transfer of the heat generated by the electronic component to the radiator while guaranteeing satisfactory electrical insulation between the radiator and the electronic component.

The aim of the invention is to meet this need and the invention does so, according to one of its aspects, using a method for producing a thermally conductive and electrically insulating connection between at least one electronic component and a radiator that is entirely or partially made of metal, the electronic component and the radiator forming part of an assembly furthermore comprising a printed circuit board placed between the electronic component and the radiator, the printed circuit board comprising at least one metal layer and a metal insert,

in which method at least one metal surface through which heat is dissipated from the electronic component to the radiator is anodized, said metal surface belonging to one of the electronic component, the printed circuit board and the radiator.

The insert may be exclusively contained in the height of the printed circuit board, i.e. the insert then does not protrude beyond the printed circuit board, neither toward the radiator nor toward the electronic component.

The printed circuit board may be exclusively placed between the electronic component and the radiator, i.e. when the radiator, the printed circuit board and the electronic component are stacked along an axis in this order, there is no plane perpendicular to this axis that cuts either both the radiator and the printed circuit board or both the printed circuit board and the electronic component.

The electronic component is for example borne by a face of the printed circuit board that defines a surface for receiving this component. In the following, the expression “face of the printed circuit board” is understood to mean an external face of the latter.

According to the invention, only a superficial surface layer may be anodized, which is not the case for example in patent U.S. Pat. No. 6,449,158 in which the aluminum layer is anodized in its entirety.

Anodizing this or these surfaces makes it possible to ensure electrical insulation without however hindering the transfer of heat from the electronic component to the radiator through said surface. Furthermore, producing this electrical insulation by anodization is less expensive.

The electronic component may comprise a package having at least one metal portion, said package resting on a receiving surface of the printed circuit board via said metal portion, and said metal portion of the package may be anodized. This anodized surface of the package then forms the or one of the anodized metal surfaces of the assembly.

The radiator may have a metal surface making contact with the printed circuit board, and said surface of the radiator may be anodized. This anodized surface of the radiator then forms the or one of the anodized metal surfaces. The radiator is for example entirely or partially made of aluminum, this material having satisfactory electrical and thermal properties while being inexpensive and light.

The radiator may be made of a single part, in which case a portion of this part is subjected to an anodization treatment. As a variant, a previously anodized part is joined to the radiator and a surface of this joined part forms the anodized metal surface of the radiator.

The metal insert may have an integral construction, for example be made of a single part.

The metal insert may be made of copper.

According to a first embodiment of the invention, the metal insert is embedded in the rest of the printed circuit board. According to this first embodiment, the printed circuit board comprises at least two metal layers, the first metal layer is interposed between the metal insert and the electronic component, and the second metal layer is interposed between the metal insert and the radiator. Each of the metal layers may be made of copper.

According to a first variant of this first embodiment, the face of the first metal layer facing the electronic component is entirely or partially anodized. This anodized face of the first metal layer then forms the or one of the anodized metal surfaces of the assembly.

According to a second variant of this first embodiment, or in combination with the first variant above, the face of the second metal layer facing the radiator is entirely or partially anodized. This anodized face of the second metal layer then forms the or one of the anodized metal surfaces of the assembly.

According to another variant of the first embodiment of the invention, or if applicable according to the first or second variant above, the metal insert may have a first contact face making contact with a corresponding contact surface of the first metal layer, and a second contact face making contact with a corresponding contact surface of the second metal layer, and at least one of the following surfaces may be anodized:

said first contact face,

said corresponding contact surface of the first metal layer,

said second contact face, and

said corresponding contact surface of said second metal layer.

Thus, this anodized surface forms the or one of the anodized metal surfaces of the assembly.

If required, the heat generated by the electronic component may be dissipated through a plurality of anodized metal surfaces.

According to a second embodiment of the invention, the metal insert may not be embedded in the rest of the printed circuit board.

The printed circuit board may comprise two metal layers, for example made of copper, and a prepreg layer, and a cavity may be produced through these layers.

The prepreg layer may represent between 20 and 90% of the thickness of the printed circuit board, for example between 50% and 80%.

The metal insert is for example placed in this cavity, especially being forcefully fitted into the latter, and has a contact face making contact with the electronic component. This contact face of the metal insert may be anodized, then forming the or one of the anodized metal surfaces of the assembly.

According to this second embodiment, when the insert is placed in the through-cavity, it may not extend into the thickness of the second metal layer, and the portion of the cavity produced in this second metal layer may be entirely or partially filled with a resin. The second metal layer may be an exterior layer of the printed circuit board, a face of the second metal layer then forming an exterior face of the printed circuit board, and the resin may be placed in the cavity so that said exterior face of the printed circuit board is substantially flat, including level with the cavity.

As a variant, the insert does not extend into the thickness of the first metal layer but into the prepreg layer and the second metal layer, and the portion of the cavity produced in the first metal layer is entirely or partially filled with a resin, as described above with respect to the second metal layer, especially as regards obtaining a flat surface.

As yet another variant, the insert extends only into a portion of the thickness of the first metal layer or the second metal layer, and the portion of the cavity not occupied by the insert in the first or second metal layer is entirely or partially filled with resin. Flat surfaces may be obtained as indicated above.

Except in the case of the first embodiment of the invention, the metal insert may have a contact face making contact with the radiator, and said contact face of the insert may be anodized. The anodized face of the insert, which belong to the printed circuit board, then forms the or one of the anodized metal surfaces of the assembly.

Another subject of the invention, according to another of its aspects, is an assembly comprising:

at least one electronic component,

a radiator that is entirely or partially made of metal, and

a printed circuit board placed between the radiator and the electronic component, said printed circuit board comprising at least one metal layer and a metal insert,

one at least of the electronic component, the printed circuit board and the radiator comprising at least one metal surface through which heat dissipated by the electronic component is transferred to the radiator, said metal surface being anodized.

The above assembly allows the advantages already mentioned above to be obtained.

The insert may be placed between the electronic component and the radiator.

All or some of the features described with regard to the above method may be combined with the assembly such as defined above.

The electronic component is for example an electronic component having a nominal power higher than 1 kW. The thermal power dissipated by this component when it is supplied with electrical power may be comprised between 10 W and 50 W, for example.

This component for example forms part of an inverter of an inverter/charger circuit furthermore comprising an electric motor and incorporated into a hybrid or electric vehicle.

Yet another subject of the invention, according to another of its aspects, is a structure for at least one electronic component, the structure comprising:

a printed circuit board one face of which defines an electronic-component receiving surface, the printed circuit board comprising a metal insert; and

a radiator that is entirely or partially made of metal, the radiator having an anodized surface facing the printed circuit board.

The radiator is for example made of aluminum, in which case the anodization allows an alumina layer to be placed in contact with the printed circuit board.

Yet another subject of the invention, according to another of its aspects, is a structure for at least one electronic component, the structure comprising:

a printed circuit board one face of which defines an electronic-component receiving surface, the printed circuit board comprising a metal insert and at least one metal layer; and

a radiator, the radiator having a surface facing the printed circuit board,

the metal insert being embedded in the rest of the printed circuit board and comprising a contact face making contact with a corresponding contact surface of the metal layer of the printed circuit board.

Yet another subject of the invention, according to another of its aspects, is a structure for at least one electronic component, the structure comprising:

a printed circuit board one face of which defines an electronic-component receiving surface, the printed circuit board comprising a metal insert; and

a radiator, the radiator having a surface facing the printed circuit board,

the metal insert being placed in a through-cavity produced in the printed circuit board so that a section of said insert forms a portion of the electronic-component receiving surface, said section of the insert being anodized.

The invention will be better understood on reading the following description of nonlimiting embodiments thereof and on examining the appended drawings in which:

FIG. 1 shows an example assembly according to the prior art, already described;

FIG. 2 schematically shows an assembly according to one variant of a first embodiment of the invention;

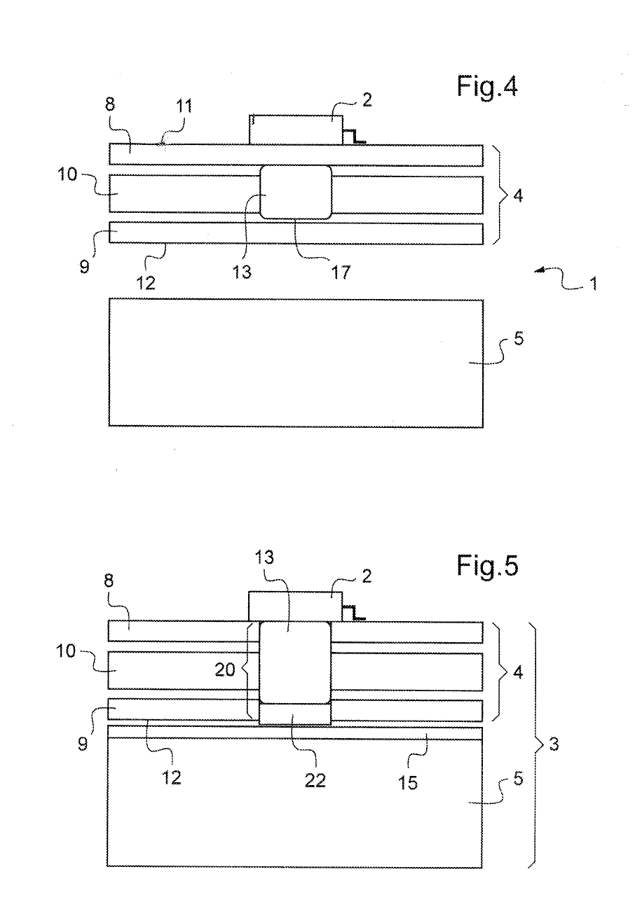

FIGS. 3 and 4 schematically show other variants of the first embodiment of the invention;

FIG. 5 schematically shows an assembly according to one variant of a second embodiment of the invention; and

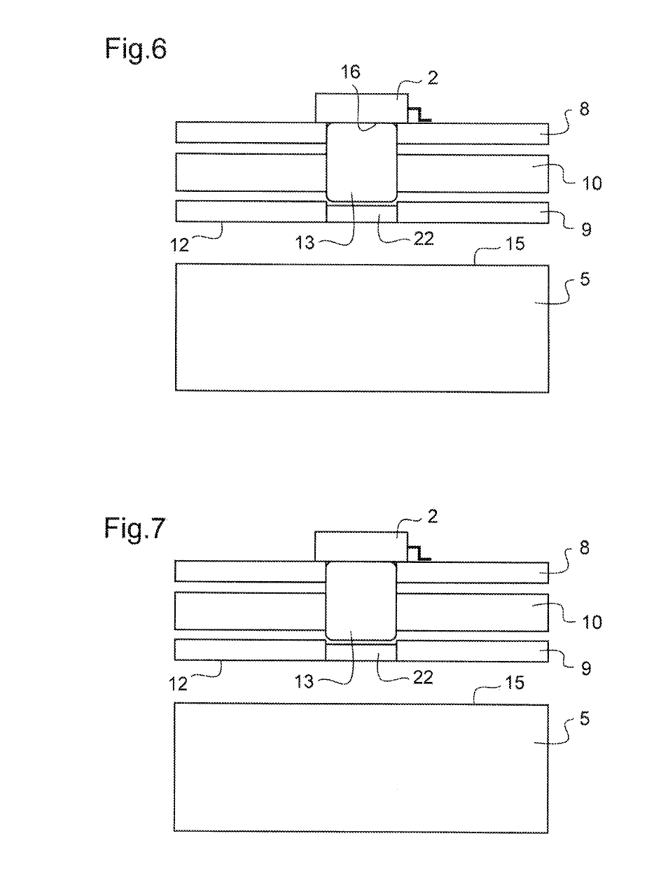

FIGS. 6 and 7 schematically show other variants of the second embodiment of the invention.

FIG. 2 shows an assembly 1 according to a first embodiment of the invention. This assembly 1 comprises an electronic component 2, for example a power transistor such as a field-effect transistor, and a structure 3 to which the component 2 has been joined, for example by soldering. The component 2 for example has a nominal power higher than or equal to 1 kW and generates, when it is supplied with electrical power, a thermal power comprised between 10 W and 50 W. The electronic component 2 may withstand a voltage of about 430 V and a current of about 13 A.

The structure 3 comprises, in the example shown, a printed circuit board 4 and a radiator 5, the radiator especially being made of aluminum. In the example considered, the printed circuit board 4 takes the form of a multilayer comprising a first copper layer 8, a second copper layer 9 and a prepreg layer 10 imprisoned between the copper layers 8 and 9.

The first copper layer 8 has a face 11 defining a receiving surface of the printed circuit board, to which surface the electronic component 2 is joined.

The second copper layer 9 has a face 12 facing the radiator 5, which defines another exterior surface of the printed circuit board 4.

As shown, the prepreg layer 10 may be thicker than each of the copper layers 8 and 9.

The printed circuit board 4 furthermore comprises a metal insert 13, for example made of copper. In the example shown in FIG. 2, the insert 13 is contained in a cavity produced only in the prepreg layer 10, and is not contained in the thickness of the copper layers 8 and 9. The insert 13 is placed, with respect to the electronic component 2 and the radiator 5, so that heat dissipated by this component 2 passes via the insert 13 to the radiator 5.

The printed circuit board 4 shown in FIG. 2 is for example that sold by Schweizer Electronic™ under the reference FR4 6L Insert In-LAY.

In the example in FIG. 2, the exterior surface 12 of the printed circuit board makes contact with an anodized surface 15 of the radiator 5. This anodized surface 15 is for example obtained by anodizing a section of the metal block forming the radiator 5.

As a variant, a metal part, for example made of aluminum, is previously anodized before being joined to the radiator 5 in order to define the contact surface of the radiator making contact with the printed circuit board 4.

This anodized surface 15 makes it possible to obtain a satisfactory electrical insulation between the electronic component 2 and the radiator 5, without adversely affecting dissipation of heat from the electronic component 2 to the radiator 5. Thus, a connection between the electronic component 2 and the radiator 5 is obtained that is electrically insulated while enabling the desired heat dissipation.

Since the surface 15 is anodized, the radiator 5 may make contact with the printed circuit board 4 via an anodized layer, said layer for example having a thickness comprised between 10 μm and 30 μm whereas the radiator is about 2 mm thick.

In the examples in FIGS. 3 and 4, which show variants of the assembly 1 in FIG. 2 before the printed circuit board 4 and the radiator 5 have been assembled, the radiator does not have an anodized surface. In the example in FIG. 3, the electrical insulation is obtained by anodizing each of the faces via which the insert 13 faces a metal layer 8 or 9.

The insert 13 for example has a face 16 facing the first copper layer 8 and a face 17 facing the second copper layer 9 and these two faces 16 and 17 are anodized. If required, the corresponding contact surfaces of the contact faces 16 and 17, which belong to the first copper layer 9 and the second copper layer 10, respectively, may also or instead be anodized.

In the example in FIG. 4, the section of the receiving surface 11 making contact with the electronic component 2, and the exterior face 12 defined by the second copper layer 9, are anodized. Again with regard to the example in FIG. 4, the electronic component 2 may comprise a package at least the portion making contact with the printed circuit board 4 of which is made of metal and this metal portion of the package may be anodized.

In another example (not shown), the assembly 1 may employ all the anodized surfaces listed in the examples of FIGS. 2 to 4.

Variants of the assembly 1 according to a second embodiment of the invention will now be described with reference to FIGS. 5 to 7.

In these examples, a cavity 20 is produced in the layers 8 to 10 of the printed circuit board 4 and the insert is forcefully fitted into this cavity 20. Here, the insert 13 is contained in the thickness of the first copper layer 8 and of the prepreg layer 10. The insert 13 makes contact via its face 16 with the electronic component 2. Nevertheless, the insert is not contained in the thickness of the second copper layer 9, so that, level with the latter, the cavity 20 is not occupied by the insert 13. The printed circuit board 4 shown in FIGS. 3 and 4 is for example that sold by Ruwel International™ under the reference FR4 2LCopper In-LAY.

A resin 22, for example a standard blue adhesiveless film of U90 2 kV/125° C. Kerartherm®, is poured into the portion of the cavity 20 produced in the second copper layer 9. The resin 22 may be placed so that the exterior surface 12 remains flat despite the presence in the second copper layer 9 of the cavity 20. The bottom edge of the resin 22 may thus lie flush with the rest of the exterior face 12.

Similarly to the example in FIG. 2, a surface 15 of the radiator 5 may be anodized, this surface 15 forming part of the radiator when the latter is of integral construction, or belonging to a previously anodized part joined to another portion of the radiator 5. If required, this anodization may be a deep anodization and form a layer that is comprised between pm and 30 pm in thickness, via which layer the radiator makes contact with the printed circuit board.

In the example in FIGS. 6 and 7, which show variants of the assembly in FIG. 5 before the printed circuit board 4 and the radiator 5 have been assembled, other means for obtaining the electrical insulation between the electronic component 2 and the radiator 5 are used.

In the example in FIG. 6, the radiator does not have an anodized surface but that face 16 of the insert which makes contact with the electronic component 2 is anodized. When the electronic component is contained in a package that has a metal section making contact with the insert 13, said metal section of this package may be anodized.

In the example in FIG. 7, the electrical insulation is obtained by anodizing the face 12 of the second copper layer 9.

In one example (not shown), the assembly 1 may employ all the anodized surfaces listed in the examples of FIGS. 5 to 7.

The invention is not limited to the examples just described.

There is no departure from the scope of the invention provided that a thermally conductive and electrically insulating connection is established between the electronic component 2 and the radiator 5 by anodizing one or more metal surfaces.

Although the expression “anodized surface” has been used, the invention encompasses not only surface anodization but also deep anodization, i.e. a section the anodized surface of which forms an exterior is also anodized over a portion of its thickness.

The expression “comprising a” or “comprising one” must be understood to mean “comprising at least one” unless otherwise specified.

1. A method for producing a thermally conductive and electrically insulating connection between at least one electronic component and a radiator that is entirely or partially made of metal, the electronic component and the radiator forming part of an assembly further comprising a printed circuit board placed between the electronic component and the radiator, one face of the printed circuit board defining a surface for receiving the electronic component, the printed circuit board comprising at least one metal layer and a metal insert, the metal insert being exclusively contained in the height of the printed circuit board, the method comprising:
anodizing at least one metal surface through which heat is dissipated from the electronic component to the radiator, said at least one metal surface belonging to one of the electronic component, the printed circuit board and the radiator.

2. The method as claimed in claim 1, in which wherein the electronic component comprises a package having at least one metal portion, said package resting on the receiving surface of the printed circuit board via said metal portion, and wherein said metal portion of the package is anodized.

3. The method as claimed in claim 1, wherein the radiator has a surface making contact with the printed circuit board and in which said surface of the radiator is anodized.

4. The method as claimed in claim 1, wherein the printed circuit board comprises at least two metal layers, the first metal layer being interposed between the metal insert and the electronic component, and the second metal layer being interposed between the metal insert and the radiator.

5. The method as claimed in claim 4, wherein the receiving surface is defined by a face of the first metal layer facing the electronic component, said receiving surface being entirely or partially anodized.

6. The method as claimed in claim 5, wherein a face of the second metal layer facing the radiator is entirely or partially anodized.

7. The method as claimed in claim 4, wherein the metal insert has a first contact face making contact with a corresponding contact surface of the first metal layer, and a second contact face making contact with a corresponding contact surface of the second metal layer, and wherein at least one selected from the group consisting of the following is anodized: said first contact face, said corresponding contact surface of the first metal layer, said second contact face, and said corresponding contact surface of said second metal layer.

8. The method as claimed in claim 1, wherein the metal insert has a contact face making contact with the electronic component, and in which said contact face of the insert is anodized.

9. The method as claimed in claim 8, wherein the printed circuit board comprises a first metal layer, a second metal layer and a prepreg layer, a through-cavity being produced through said layers, the portion of said cavity produced in the second metal layer being entirely or partially filled with a resin.

10. An assembly comprising:
at least one electronic component;
a radiator that is entirely or partially made of metal; and
a printed circuit board placed between the radiator and the at least one electronic component, said printed circuit board having a face defining a surface for receiving the electronic component, and said printed circuit board comprising at least one metal layer and a metal insert, the metal insert being exclusively contained in the height of the printed circuit board, wherein
one at least of the electronic component, the printed circuit board and the radiator comprises at least one metal surface through which heat dissipated by the electronic component is transferred to the radiator, said metal surface being anodized.

11. The assembly as claimed in claim 10, the metal insert being made of a single part.
